(19) United States
(12) Patent Application Publication
(10) Pub. No.: US 2005/0160349 A1
(43) Pub. Date: Jul. 21, 2005

(54) Channel coding method and device

(75) Inventors: Kyung-Whoon Cheun, Seoul (KR); Yung-Soo Kim, Seongnam-si (KR); Wang-Rok Oh, Pohang-si (KR)

Correspondence Address: DILWORTH & BARRESE, LLP, 333 EARLE OVINGTON BLVD., UNIONDALE, NY, 11553, US

(73) Assignees: SAMSUNG ELECTRONICS CO., LTD., Gyeonggi-do (KR); Seoul National University Industry Foundation, Seoul (KR)

(21) Appl. No.: 11/020,768

(22) Filed: Dec. 23, 2004

(30) Foreign Application Priority Data
Dec. 24, 2003 (KR) 96679-2003

(51) Int. Cl. H03M 13/03

(52) U.S. Cl. 714/790

(57) ABSTRACT

A channel coding method and device using an RA method and puncturing are provided. In the channel coding method, the input information bits are repeated according to a repetition factor, interleaved, and accumulated. The accumulated bit stream and the information bits are converted to a serial bit stream and punctured according to a puncturing pattern. Thus, a codeword with a required coding rate is generated.

### PRIORITY

This application claims priority under 35 U.S.C. § 119 to an application entitled “Improved Channel Coding Method and Device” filed in the Korean Intellectual Property Office on Dec. 24, 2003 and assigned Serial No. 2003-96679, the contents of which are incorporated herein by reference.

### BACKGROUND OF THE INVENTION

1. Field of the Invention

The present invention relates generally to a mobile communication system, and in particular, to a channel coding device and a method for minimizing coding complexity through Repeat and Accumulate (RA) and puncturing and providing an improved Bit Error Rate (BER) and Frame Error Rate (FER) performance.

2. Description of the Related Art

Along with the recent increase in the discussion of the 4^{th} generation (4G) mobile communication service, the need for its standardization has become high. It is expected that an RA code having better error correction performance than a turbo code will be adopted as a channel coding method for a 4G mobile communication system. Hence, the channel coding schemes have been proposed for efficiently supporting the RA coding gain and various coding rates.

FIG. 1 is a block diagram of a conventional RA coder with a coding rate of 1/q. Referring to FIG. 1, N information bits occur q times in a repeater 102 and the qN bits are interleaved in an interleaver 104 of size qN. The interleaved bits are accumulated to form an RA codeword in a binary accumulator 106. Thus, for the input of N information bits, qN coded bits are output.

As illustrated in FIG. 1, the reciprocal of the repetition factor for the repeater 102, 1/a, is the coding rate of the RA code, and the repetition factor q must be at least ⅓ to achieve a coding gain. That is, for an RA code, its coding rate must be ⅓ or lower to achieve a coding gain. Therefore, if a higher coding rate is required, the RA code is not viable.

An irregular RA code was proposed to improve the performance of the regular RA code. Despite better BER and FER performance than the RA code, the irregular RA code requires very complex coding processes.

For irregular RA coding, all of the bits in an input information bit frame are grouped into several groups and each information bits is repeated a different number of times according to its group. The number of the groups, a ratio of the bits for each group, and a repetition factor for each group must be appropriately determined according to a coding rate. As an example, let the length of the information frame be denoted by N, the number of the entire groups be denoted by J, and a repetition factor for bits in an ith group be denoted by fᵢ. Then, the total number of bits input to the interleaver is

$$N {\sum }_{i = 1} {if}_{i}$$

and thus the interleaver size is

$$N {\sum }_{i = 1} {if}_{i} . N {\sum }_{i = 1} {if}_{i}$$

interleaved bits are grouped, each group having “a” number of bits prior to input into a binary accumulator. Only if the value “a” is appropriately set according to a required coding rate taking into consideration an irregular repetition factor, the number of the groups, and a ratio of bits for each group, a good coding gain can be achieved.

Accordingly, for the irregular RA coder, the number of groups, a ratio of information bits for each group, and a repetition factor for the information bits in each group are predetermined according to the length of an input information bit frame as well as a coding rate. The number of bits to be in each group formed out of interleaved bits and fed to the binary accumulator is also predetermined. Since these parameters vary with the coding rate and the frame length, a change in the coding rate or the frame length leads to new setting of the parameters. As a result, a considerable modification is made to the structure of the irregular RA coder.

The average repetition factor of the irregular RA code having a relatively excellent performance is much greater that the repetition factor of the RA code. Thus, the interleaver size is increased for coding and a deinterleaver size is also increased for decoding. While the value “a” used in the irregular RA coding varies with a coding rate, it is usually much greater than 1, thereby increasing decoding complexity. If a interleaved bits are fed simultaneously to the binary accumulator, the following computation is carried out (a+2) times, as set forth in Equation 1:.

$$CHK ( x , y ) = log \frac{1 + tanh \frac{x}{2} tanh \frac{y}{2}}{1 + tanh \frac{x}{2} tanh \frac{y}{2}} \qquad ( 1 )$$

FIG. 2 is a block diagram of a conventional irregular RA coder. Referring to FIG. 2, information bits are repeated, each as many times as a predetermined repetition factor in an irregular repeater 202 and interleaved in an interleaver 204 of size

$$N {\sum }_{i = 1} {if}_{i} .$$

The interleaved bits are grouped, each group having “a” bits in a serial-to-parallel (S/P) converter 206 and accumulated in a binary accumulator 208. The accumulated bits and the final input information bits are converted to a serial bit stream as a codeword in a parallel-to-serial (P/S) converter 210.

Despite the advantage of better BER and FER performance than the regular RA code, the irregular RA code has the drawbacks of a considerable change in the structure and operation of the irregular RA coder according to a coding rate and an information frame length, and a high decoding complexity because of the irregular repetition factor fᵢ used in the irregular repeater 202, the total number of groups J, and since the value “a” varies with the coding rate and the information frame length.

### SUMMARY OF THE INVENTION

An object of the present invention is to substantially solve at least the above problems and/or disadvantages and to provide at least the advantages below. Accordingly, an object of the present invention is to provide a channel coding method and a device for efficiently supporting various coding rates and various information bit frame lengths with better BER and FER performance than the conventional RA codes.

Another object of the present invention is to provide a channel coding method and a device for facilitating coding with low coding complexity at various coding rates with respect to various information bit frame lengths.

The above objects are achieved by providing a channel coding method and a device using RA and puncturing. According to one aspect of the present invention in a channel coding method, the input information bits are repeated according to a predetermined repetition factor, interleaved, and accumulated. The accumulated bit stream and the information bits are converted to a serial bit stream and punctured in a predetermined puncturing pattern. Thus, a codeword with a required coding rate is generated.

The accumulated bit stream is generated by performing binary summation on the interleaved bit stream and a previous accumulated bit stream.

The coding rate is determined by the repetition factor and the puncturing pattern. In the puncturing step, only the accumulated bit stream is punctured, or all of the information bits are punctured and, if an additional puncturing is required, the accumulated bit stream is additionally punctured, or the information bits and the accumulated bit stream are punctured at a predetermined ratio.

According to another aspect of the present invention, in a channel coding device, a repeater repeats the input information bits according to a predetermined repetition factor, an interleaver interleaves the repeated bit stream, an accumulator accumulates the interleaved bit stream, a P/S converter converts the accumulated bit stream and the information bits received in parallel to a serial bit stream, and a puncturer generates a codeword with a required coding rate by puncturing the serial bit stream in a predetermined puncturing pattern.

The accumulator includes a binary accumulation unit having a first and a second input port and one output port, for performing a binary summation on the interleaved bit stream received through the first input port and a previous accumulated bit stream of the puncturer received from the second input port, and a delay for outputting an accumulated bit stream received from the binary accumulation unit to the second input port of the binary accumulation unit.

The coding rate is determined by the repetition factor and the puncturing pattern in the coding device.

The puncturer punctures only the accumulated bit stream, punctures all of the information bits and, if an additional puncturing is required, the accumulated bit stream, or punctures the information bits and the accumulated bit stream at a predetermined ratio.

According to a further aspect of the present invention in a channel coding device, a repeater repeats the input information bits according to a predetermined repetition factor, a first coder generates a first coded bit stream by encoding the repeated bit stream, an interleaver interleaves the first coded bit stream, a second coder generates a second coded bit stream by encoding the interleaved bit stream, and a puncturer generates a codeword with a required coding rate by puncturing the second coded bit stream in a predetermined puncturing pattern.

According to still another aspect of the present invention, in a channel coding device, a first coder generates a first coded bit stream by encoding input information bits, a repeater repeats the first coded bit stream according to a predetermined repetition factor, an interleaver interleaves the first coded bit stream, a second coder generates a second coded bits stream by encoding the interleaved bit stream, and a puncturer generates a codeword with a required coding rate by puncturing the second coded bit stream in a predetermined puncturing pattern.

### BRIEF DESCRIPTION OF THE DRAWINGS

The above and other objects, features and advantages of the present invention will become more apparent from the following detailed description when taken in conjunction with the accompanying drawings in which:

FIG. 1 is a block diagram of a conventional RA coder with a coding rate of 1/q;

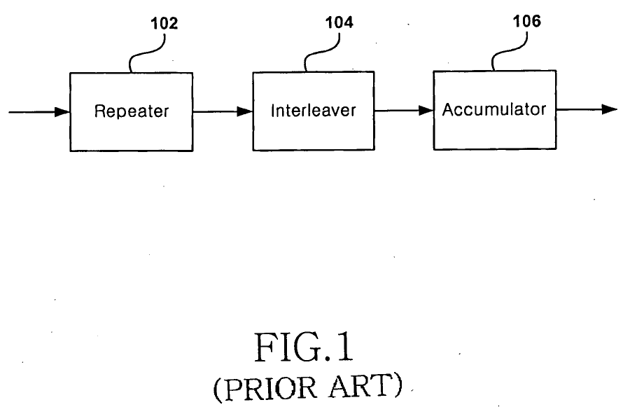

FIG. 2 is a block diagram of a conventional irregular RA coder;

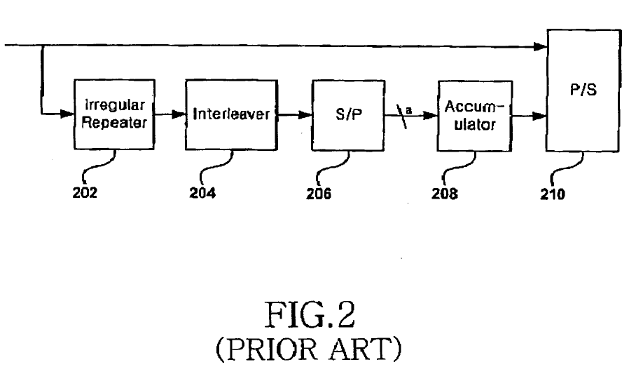

FIG. 3 is a block diagram of a coder according to an embodiment of the present invention;

FIG. 4 is a block diagram of an accumulator in the coder illustrated in FIG. 3;

FIG. 5 is a block diagram of a coder according to another embodiment of the present invention;

FIG. 6 is a block diagram of a coder according to a third embodiment of the present invention; and

FIG. 7 is a graph illustrating a comparison in performance between the inventive coder with a coding rate of ½ and conventional coders with code rates of ½ and ⅓.

### DETAILED DESCRIPTION OF THE PREFERRED EMBODIMENTS

Preferred embodiments of the present invention will be described herein below with reference to the accompanying drawings. In the following description, well-known functions or constructions are not described in detail since they would obscure the invention in unnecessary detail.

As described earlier, the conventional RA coding method is not viable for a high coding rate. The conventional irregular RA coding, which offers improved BER and FER performance, increases coding and decoding complexity and requires a great change in the operation and structure of an irregular RA coder according to a coding rate and an information bit frame length. That is why the conventional irregular RA coding cannot support the various coding rates and the various information bit frame lengths. On the other hand, the present invention provides an optimum RA coding method that efficiently supports the various coding rates and the various information bit frame lengths through a repetition and a puncturing process, and offers a better BER and a FER performance than the RA code.

An RA coder of the present invention can be constructed by combining an existing RA coder and puncturer. Therefore, coding complexity is low and coding is easily performed for the various coding rates and the various information bit frame lengths.

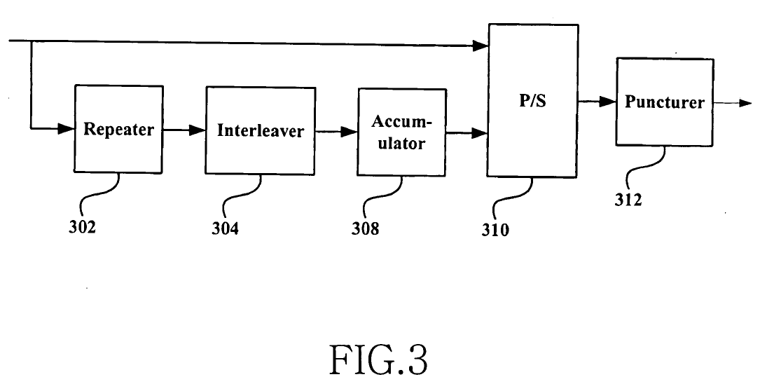

FIG. 3 is a block diagram of a coder according to an embodiment of the present invention. Referring to FIG. 3, the coder includes a repeater 302 for repeating the input information bits a predetermined number of times, an interleaver 304 for interleaving the repeated bits, an accumulator 308 for accumulating the interleaved bits, a P/S converter 310 for serializing the accumulated bits and information bits, and a puncturer 312 for puncturing the serial bit stream according to a required coding rate.

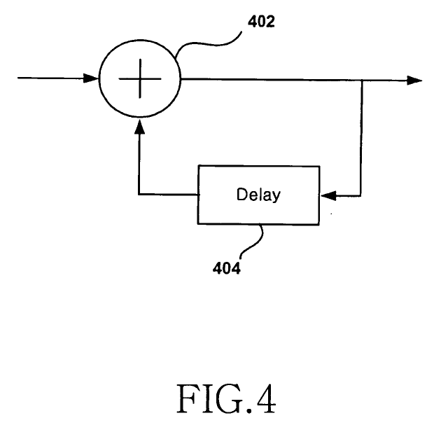

FIG. 4 is a block diagram of the accumulator 308. Referring to FIG. 4, the accumulator 308 includes a binary accumulation unit 402 having two input ports and a delay 404 for outputting the previous output of the binary accumulation unit 402 to one of the two input ports of the binary accumulation unit 402. Thus, the output of the accumulator 308 is determined according to the current input of the binary accumulation unit 402 and the previous output of the accumulator 308.

The coder of the present invention can offer various coding rates. A final coding rate is achieved by puncturing only the output of the accumulator 308, or if all of the information bits are punctured and additional puncturing is needed, puncturing the output of the accumulator 308, or puncturing the output of the accumulator 308 and the information bits at a predetermined ratio.

The coding rate of the coder is determined by a repetition factor for the repeater 302 and a puncturing rate for the puncturer 312, as described above. If the required final coding rate is 1/q and an information frame having N information bits is input to the coder, each bit occurs q′ times in the repeater 302. q′ is greater than 1=1/r (r is a coding rate) all the time. q′N repeated bits are interleaved in the interleaver 304 of size q′N and applied to the input of the accumulator 308. The output of the accumulator 308 and the information bits are serialized in the P/S converter 310 and punctured in a predetermined puncturing pattern in the puncturer 312.

The puncturer 312 punctures N(q′−q+1) bits in N(1+q′) bits and outputs the remaining Nq bits. When necessary, the puncturer 312 may use different puncturing rates for the directly input information bits and the output bits of the accumulator 308. Therefore, the ratio between the information bits and the accumulated bits included in the Nq coded bits can be controlled.

The size of the interleaver 304 is determined by the repetition factor of the repeater 302 and the puncturing rate of the puncturer 312. Therefore, the interleaver size can be controlled irrespective of the coding rate. It is known that as the interleaver size increases, coding performance is better. Hence, control of the repetition factor and the puncturing rate leads to a desired interleaver size irrespective of the coding rate. The resulting large interleaver gain increases the coding gain of the coder.

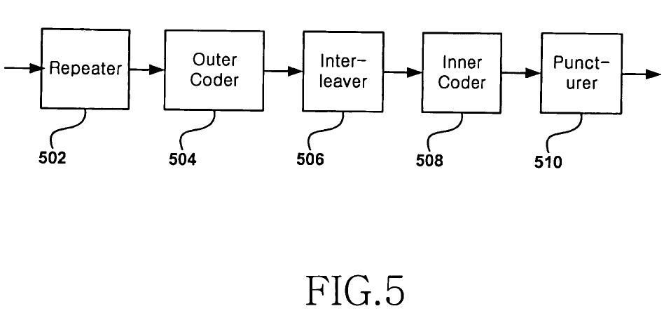

FIG. 5 is a block diagram of a coder according to another embodiment of the present invention. Referring to FIG. 5, two constituent coders 504 and 508 are connected in series with an interleaver 506 connected between the two constituent codes 504 and 508. An input signal is repeated a predetermined number of times in a repeater 502, encoded in the outer coder 504, interleaved in the interleaver 506, secondarily coded in the inner coder 508, and punctured in a predetermined puncturing pattern in a puncturer 510. Thus, a codeword with a required coding rate is output. The input signal is repeated according to a repetition factor of n in the repeater 502 and provided to the outer coder 504. In this manner, the size of the interleaver 506 for a concatenated code can be increased by N times, to thereby increase the interleaving gain. A final coding rate can be adjusted through the control of the puncturing rate in the puncturer 510 at the output end of the inner coder 508. By repeating the input signal according to the repetition factor of n and puncturing (n−1) bits in the input n bits, the same coding rate as in a typical coder is achieved and the interleaving gain is increased.

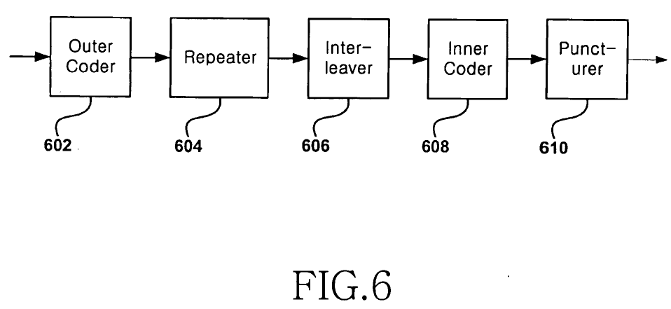

FIG. 6 is a block diagram of a coder according to a third embodiment of the present invention. Referring to FIG. 6, an outer coder 602 and an inner coder 608 are connected in series with an interleaver 606 located between the outer coder 602 and the inner coder 608. The output of the outer coder 602 is applied to the input of the interleaver 606 through a repeater 604. The input signal is interleaved in the interleaver 606, coded in the inner coder 608, and punctured in a predetermined puncturing pattern in a puncturer 610. Thus, a codeword with a required coding rate is output. The coded bits of the outer coder 602 are repeated according to a repetition factor of n in the repeater 604. Therefore, an interleaver size in the coder is increased by N times, to thereby increase the interleaving gain of a concatenated code. A final coding rate can be adjusted through the control of the puncturing rate in the puncturer 610 at the output end of the inner coder 608. By repeating the output of the outer coder 602 according to the repetition factor of n and puncturing (n−1) bits in the input n bits in the puncturer 610, the same coding rate as in a typical coder is achieved and the interleaving gain is increased.

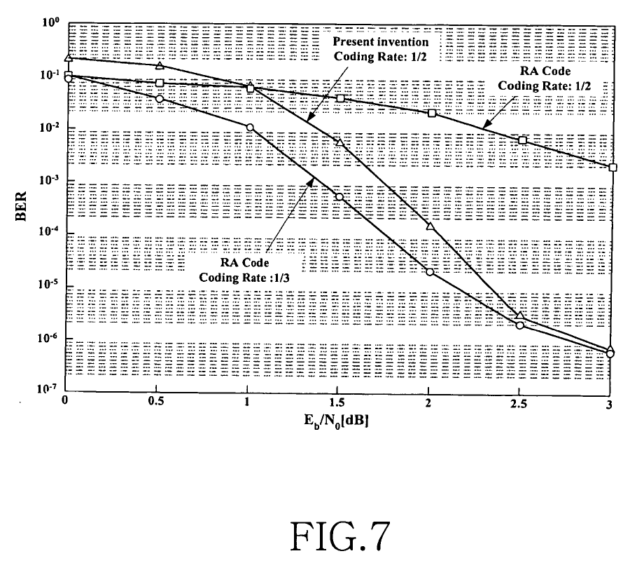

FIG. 7 is a graph illustrating a comparison in performance between the inventive coder with a coding rate of ½ and conventional coders with code rates of ½ and ⅓. A simulation was performed under the conditions that the length of an information frame is 1024 (N=1024), a repetition factor is 3 (q′=3), a coding rate is ½ (r=1/q=½), all information bits are punctured and (q′−q)N bits are punctured from among the total of the q′N output bits of an accumulator, and a uniform interleaver is used.

Referring to FIG. 7, the inventive coding method provides better BER performance than the conventional RA coding method with the same coding rate. At a high signal-to-noise ratio (SNR) area, the present invention offers a performance approximate to that of an RA code under the same interleaver size, that is, a lower coding rate-RA code.

In accordance with the present invention as described above, a coder is constructed by combining an existing RA coder and a puncturer having a regular puncturing pattern. Therefore, a coding complexity is low and the coding is easily performed with respect to the various coding rates and the various information frame lengths.

The coding method of the present invention facilitates system implementation because decoding complexity is much less than that of the irregular RA code.

In the coding method of the present invention, a coding rate is easily controlled through a repetition and a puncturing process of an input signal. Thus, the coding method is effective in a retransmission algorithm for supporting various coding rates, such as HARQ (Hybrid Automatic Retransmission request).

While the invention has been shown and described with reference to certain preferred embodiments thereof, it will be understood by those skilled in the art that various changes in form and details may be made therein without departing from the spirit and scope of the invention as defined by the appended claims.

1. A channel coding method comprising the steps of:
(1) repeating input information bits according to a repetition factor;
(2) interleaving the repeated information bits;
(3) accumulating the interleaved bits;
(4) converting the accumulated bits and the information bits to a serial bit stream; and
(5) generating a codeword with a required coding rate by puncturing the serial bit stream according to a puncturing pattern.

2. The channel coding method of claim 1, wherein step (3) comprises the step of generating the accumulated bit stream by performing binary summation on the interleaved bits and previously accumulated bits.

3. The channel coding method of claim 1, wherein the coding rate is determined by the repetition factor and the puncturing pattern.

4. The channel coding method of claim 1, wherein step (5) comprises the step of puncturing only the accumulated bits.

5. The channel coding method of claim 1, wherein step (5) comprises the steps of:
puncturing all of the information bits; and
if an additional puncturing is required, puncturing the accumulated bits.

6. The channel coding method of claim 1, wherein step (5) comprises the step of puncturing the information bits and the accumulated bits at a ratio.

7. The channel coding method of claim 1, wherein step (5) comprises one of the steps of:
puncturing only the accumulated bits;
puncturing all of the information bits and if an additional puncturing is required, puncturing the accumulated bits; and
puncturing the information bits and the accumulated bits at a ratio.

8. A channel coding device comprising:
a repeater for repeating input information bits according to a repetition factor;
an interleaver for interleaving the repeated bits;
an accumulator for accumulating the interleaved bits;
a parallel-to-serial converter for converting the accumulated bits and the information bits received in parallel to a serial bit stream; and
a puncturer for generating a codeword with a required coding rate by puncturing the serial bit stream according to a puncturing pattern.

9. The channel coding device of claim 8, wherein the accumulator includes:
a binary accumulation unit having a first and a second input port and one output port, for performing binary summation on the interleaved bits received through the first input port and previously accumulated bits of the puncturer received from the second input port; and
a delay for outputting an accumulated bit stream received from the binary accumulation unit to the second input port of the binary accumulation unit.

10. The channel coding device of claim 8, wherein the coding rate is determined by the repetition factor and the puncturing pattern.

11. The channel coding device of claim 8, wherein the puncturer punctures only the accumulated bits.

12. The channel coding device of claim 8, wherein the puncturer punctures all of the information bits and, if an additional puncturing is required, punctures the accumulated bits.

13. The channel coding device of claim 8, wherein the puncturer punctures the information bits and the accumulated bits at a ratio.

14. The channel coding device of claim 8, wherein the puncturer punctures only the accumulated bits, punctures all of the information bits and, if an additional puncturing is required, punctures the accumulated bits, or punctures the information bits and the accumulated bits at a ratio.

15. A channel coding device comprising:
a repeater for repeating input information bits according to a repetition factor and generating a repeated bit stream;
a first coder for generating a first coded bit stream by encoding the repeated bit stream;
an interleaver for interleaving the first coded bit stream;
a second coder for generating a second coded bit stream by encoding the interleaved bit stream; and
a puncturer for generating a codeword with a required coding rate by puncturing the second coded bit stream according to a puncturing pattern.

16. The channel coding device of claim 15, wherein the coding rate is determined by the repetition factor and the puncturing pattern.

17. The channel coding device of claim 16, wherein the puncturer punctures only the accumulated bit stream, punctures all of the information bits and, if an additional puncturing is required, punctures the accumulated bit stream, or punctures the information bits and the accumulated bit stream at a predetermined ratio.

18. A channel coding device comprising:
a first coder for generating a first coded bit stream by encoding input information bits;
a repeater for repeating the first coded bit stream according to a repetition factor;
an interleaver for interleaving the first coded bit stream;
a second coder for generating a second coded bit stream by encoding the interleaved bit stream; and
a puncturer for generating a codeword with a required coding rate by puncturing the second coded bit stream according to a puncturing pattern.

19. The channel coding device of claim 18, wherein the coding rate is determined by the repetition factor and the puncturing pattern.

20. The channel coding device of claim 19, wherein the puncturer punctures only the accumulated bit stream, punctures all of the information bits and, if an additional puncturing is required, punctures the accumulated bit stream, or punctures the information bits and the accumulated bit stream at a ratio.
